(19) United States
(12) Patent Application Publication
(10) Pub. No.: US 2024/0347599 A1
(43) Pub. Date: Oct. 17, 2024

(54) Silicon carbide semiconductor device

(71) Applicant: Fast SiC Semiconductor Incorporated, Hsinchu (TW)

(72) Inventors: Cheng-Tyng YEN, Hsinchu (TW); Hsiang-Ting HUNG, Hsinchu (TW); Fu-Jen HSU, Hsinchu (TW)

(21) Appl. No.: 18/756,691

(22) Filed: Jun. 27, 2024

Related U.S. Application Data
(63) Continuation-in-part of application No. 18/490,975, filed on Oct. 20, 2023.
(60) Provisional application No. 63/418,603, filed on Oct. 23, 2022.
(60) Provisional application No. 63/437,749, filed on Jan. 8, 2023.

(51) Int. Cl. H01L 29/10; H01L 27/088; H01L 29/06; H01L 29/08; H01L 29/16; H01L 29/78

(52) U.S. Cl. CPC H01L 29/1033; H01L 27/088; H01L 29/0696; H01L 29/086; H01L 29/0878; H01L 29/1608; H01L 29/7801

(57) ABSTRACT

A silicon carbide semiconductor device comprises a substrate, a drift layer, a plurality of first doped regions, a plurality of second doped regions, a plurality of third doped regions, a gate insulator, a gate electrode, and a source electrode. The drift layer is disposed on the silicon carbide substrate. The first doped regions are disposed in an active region of the drift layer. The second doped regions are disposed in the first doped regions. The third doped regions are disposed in the first doped regions and adjacent to the second doped regions. The third doped regions are at least partially extended with the first and second doped regions along a direction. The first doped regions, the second doped regions and the third doped regions are configured to form a multi-stripe structure in the direction in a plan view of the silicon carbide semiconductor device.

### FIELD OF THE INVENTION

The present disclosure relates to a silicon carbide semiconductor device and more particularly to a silicon carbide semiconductor device with a hybrid gate structure.

### BACKGROUND OF THE INVENTION

Silicon carbide (SiC) power devices have emerged as a promising material for power transistors in power conversion applications. Power transistors include metal-oxide-semiconductor field effect transistors (MOSFET), insulated gate bipolar transistors (IGBT), heterostructure field effect transistors (HFET), junction field effect transistors (JFET) and high electron mobility transistors (HEMT). SiC power transistors such as SiC MOSFETs have the advantages of high input impedance, lower driving loss, lower on-resistance, high blocking voltage, lower switching loss, faster switching speed, and larger safe operating area compared to their silicon counterparts.

One of the key considerations of SiC MOSFET is to reduce the on-resistance in a specified area. The total on-resistance of SiC MOSFET includes channel resistance, JFET resistance, contact resistance, drift resistance and substrate resistance. The active region of SiC MOSFET is comprised by an array of unit cells, and one of strategies to reduce the total on-resistance is to increase the channel width density to reduce channel resistance by reducing the cell pitch. Improving the channel resistance is particular important for SiC MOSFET because the channel mobility of SiC MOSFET is much lower than Si MOSFET, and the channel resistance may account for more than 40% of total on-resistance in 650V rated SiC MOSFETs. However, the JFET resistance will increase with a narrow JFET region of reduced cell pitch. To avoid the increased JFET resistance exceeds the reduced channel resistance, a current spreading layer (CSL), which is a layer with a doping concentration higher than the drift layer, is usually introduced to mitigate the JFET effect. The JFET resistance reduces with increasing doping concentration of CSL, but the blocking voltage will be reduced if the doping concentration of CSL is too high. To reduce on-resistance by reducing the cell pitch needs optimizing the trade-off between CSL doping and blocking voltage and requires better process control, which pose a challenge to manufacturing SiC MOSFET with high yield. The other limitation of further reducing the cell pitch is the minimum dimension of source contact openings. The n+ regions and p+ regions have to connect to the source electrode through the source contact openings. The width of contact openings has to shrink with shrinking cell pitch, and a narrow, high aspect ratio source contact openings may impact the performance, yield and reliability of SiC MOSFETs.

### SUMMARY OF THE INVENTION

In view of this, it is necessary to provide an improved semiconductor device to reduce on-state resistance without deficiencies related to the breakdown voltage and a method for fabricating the same.

An objective of the invention is to provide a silicon carbide semiconductor device, which can improve the performance of the silicon carbide semiconductor device.

An example of the present disclosure relates to a silicon carbide semiconductor device. The silicon carbide semiconductor device comprises a silicon carbide substrate, a drift layer of a first conductivity type, a plurality of first doped regions of a second conductivity type opposite to the first conductivity type, a plurality of second doped regions of the first conductivity type, a plurality of third doped regions of the second conductivity type, a gate insulator, a gate electrode, and a source electrode. The drift layer has a first doping concentration and is disposed on the silicon carbide substrate, wherein the drift layer has a main surface and comprises an active region. The first doped regions are disposed in the active region and comprise a plurality of first extending portions extended laterally along a first direction and a plurality of first connecting portions extended laterally along a second direction different from the first direction. Each of the first connecting portions laterally connects a pair of the first extending portions in the second direction, and the first doped regions form a plurality of first p-n junctions and a plurality of JFET regions with the drift layer. The second doped regions are disposed within the first doped regions and comprise a plurality of second extending portions extended laterally along the first direction and a plurality of second connecting portions extended laterally along the second direction. Each of the second connecting portions laterally connects a pair of the second extending portions in the second direction, and the second doped regions form a plurality of second p-n junctions with the first doped regions. A plurality of channel regions are provided between the first p-n junctions and the second p-n junctions along the main surface. The third doped regions are disposed in the first extending portions of the first doped regions and adjacent to the second extending portions of the second doped regions. The third doped regions at least partially extend with the first and second extending portions along the first direction. The gate insulator is disposed on the main surface and extends over the JFET regions, the channel regions, and a part of the second doped regions. The gate electrode contacts the gate insulator. The source electrode contacts at least a portion of the second extending portions of second doped regions and the third doped regions through a plurality of contact openings.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross sectional view of the unit cell in a typical power MOSFET.

FIG. 2 is a schematic plan view of a silicon carbide semiconductor device according to an embodiment of the present specification.

FIG. 3A depicts a perspective view of the structure along cutting line A1-A2 and line A1-A3 in FIG. 2.

FIG. 3B depicts a perspective view of the structure along cutting line A4-A5 and line A4-A3 in FIG. 2.

FIG. 3C depicts a perspective view of the structure along cutting line A6-A5 and line A6-A7 in FIG. 2.

FIG. 4 is a schematic perspective view depicting the structure of the semiconductor device according to the embodiment of FIG. 2.

FIG. 5 is a schematic plan view of a silicon carbide semiconductor device according to another embodiment of the present specification.

FIG. 6 depicts a perspective view of the structure along cutting line B1-B2 and line B1-B3 in FIG. 5.

### DETAILED DESCRIPTION OF THE PREFERRED EMBODIMENTS

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

As used herein, the term “and/or” includes any and all combinations of one or more of the associated listed items.

In the drawings, the thickness of layers and regions are exaggerated for clarity. It will also be understood that when an element such as a layer, portion, region, or substrate is referred to as being “on”, “overlie” or “atop” another element, it can be directly on, directly overlie or directly atop the other element or intervening elements may also be present. In contrast, when an element is referred to as being “directly on”, “directly overlie” or “directly atop” another element, there are no intervening elements present.

Relative terms may be used herein to describe a relationship of one element, layer, portion, or region to another element, layer, portion, or region as illustrated in the figures. It will be understood that these terms and those discussed above are intended to encompass different orientations of the device in addition to the orientation depicted in the figures. A number of embodiments will be explained below, identical structural features are identified by identical or similar reference symbols in the figures. As used herein, “lateral” or “lateral direction” should be understood to mean a direction or extent that runs generally parallel to the lateral extent of the semiconductor device. The lateral direction thus extends generally parallel to its surfaces or sides.

The terminology used herein is for the purpose of describing particular embodiments only and is not intended to be limiting of the disclosure. As used herein, the singular forms “a”, “an”, and “the” are intended to include the plural forms as well, unless the context clearly indicates otherwise. It will be further understood that the terms “comprises”, “comprising”, “includes”, and/or “including” when used herein specify the presence of stated features, elements, and/or components, but do not preclude the presence or addition of one or more other features, elements, components, and/or groups thereof. The indefinite articles and the definite articles shall encompass both the plural and singular unless the opposite is clearly apparent from the context.

In this specification, n-doped is referred to as first conductivity type while p-doped is referred to as second conductivity type. Alternatively, the semiconductor devices can be formed with opposite doping relations so that the first conductivity type can be p-doped and the second conductivity type can be n-doped. Furthermore, some Figures illustrate relative doping concentrations by indicating “−” or “+” next to the doping type. For example, “n−” means a doping concentration which is less than the doping concentration of an “n”-doping region while an “n+”-doping region has a larger doping concentration than the “n”-doping region. However, indicating the relative doping concentration does not mean that doping regions of the same relative doping concentration have to have the same absolute doping concentration unless otherwise stated. For example, two different n+-doping regions can have different absolute doping concentrations. The same applies, for example, to an n+-doping and a p+-doping region.

While properties, materials, dimensions, shapes, positional interrelationships, conditions for implementation, or the like of respective components have been described in the present disclosure, those are mere examples in all aspects, and each of the embodiments is not limited to those described. Accordingly, numerous modifications which are not illustratively described are conceivable within the scope of each of the embodiments.

A power transistor comprises an active region with a plurality of unit cells comprising the basic MOS structures connected in parallel, which can be used to control the turn-on and turn-off of voltage and current and is the fundamental component of all kinds of power converters and inverters. The power MOSFETs are one of the most popular power transistors, and the majority of power MOSFETs are normally-off (N-channel) MOSFETs, which comprise three terminals, gate, source and drain, the devices are at off-state and blocking a certain drain-to-source voltage (V_{DS}) when the applied bias between gate and source (V_{GS}, gate-to-source voltage) is equal to or lower than zero, and turn on when the applied V_{GS} is higher than the threshold voltage, where the drain current (I_{D}) flowing between the drain and source terminals.

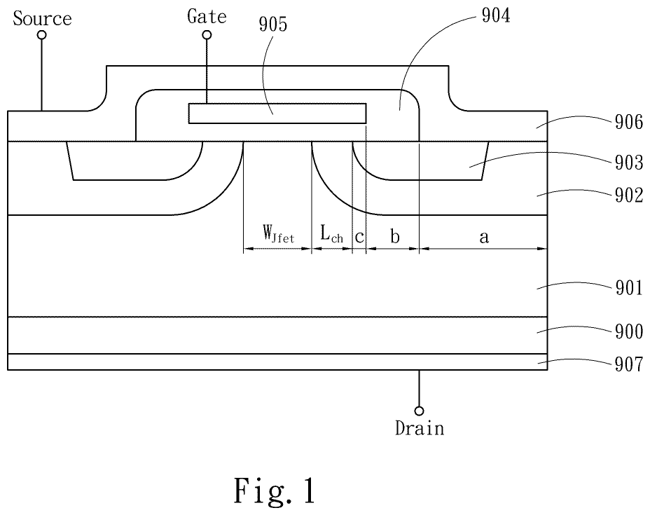

FIG. 1 shows a unit cell structure in a typical power SiC MOSFET. The power MOSFET comprises an N+ substrate 900, an N-type drift layer 901, a P well region 902 and a N+ region 903, a gate insulator 904, a gate electrode 905, a first metal 906 and a second metal 907. The gate electrode 905 is connected to a gate, the first metal 906 is connected to a source and the second metal 907 is connected to a drain. In FIG. 1, “a” denotes a half width of a contact opening, “b” denotes a distance between the contact opening and the gate electrode 905 and “c” denotes an overlap between the gate electrode 905 above the N+ region 903. Furthermore, L_{ch} denotes the channel length, and W_{jfet} denotes a width of the JFET region. Taking FIG. 1 as the example, the cell pitch of a unit cell may be calculated using Eq. (1) for a conventional stripe layout.

$$cell pitch ( {U}_{cell} ) = 2 \times ( a + b + c + {L}_{ch} ) + {W}_{JFET} \qquad ( 1 )$$

The channel width W_{ch} is a width of the channel which is extended along a direction perpendicular to the paper. Therefore, the channel width density D_{ch}, which is an areal density of the channel width, is calculated using Eq. (2).

$${D}_{ch} = \frac{2 \times {W}_{ch}}{{W}_{ch} \times {U}_{cell}} = 1 / {U}_{cell} \qquad ( 2 )$$

To shrink the cell pitch and increase the channel width density, the above mentioned dimensions (such as a, b, and c) have to be as small as possible. Some of the dimensions can be reduced by improving the photolithography and etching processes. However, there are limitations of reducing the dimension of the contact openings. When electric current flows through the channel and the N+ region 903, and finally into the contact openings, there is a current-crowding effect near the edge of the contact openings. If the width of the contact openings is too small, the total contact resistance will increase significantly, which leads to diminish or even offset the benefits brought by the higher channel width density. Conclusively, the following embodiments of the present specification aim to provide a structure and layout of a silicon carbide semiconductor device with an improved channel width density without increasing the contact resistance.

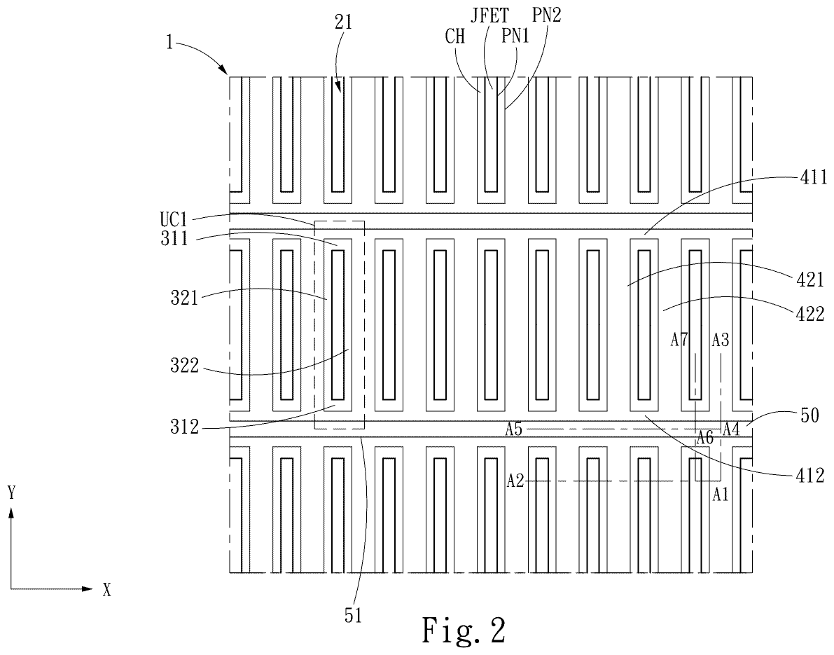

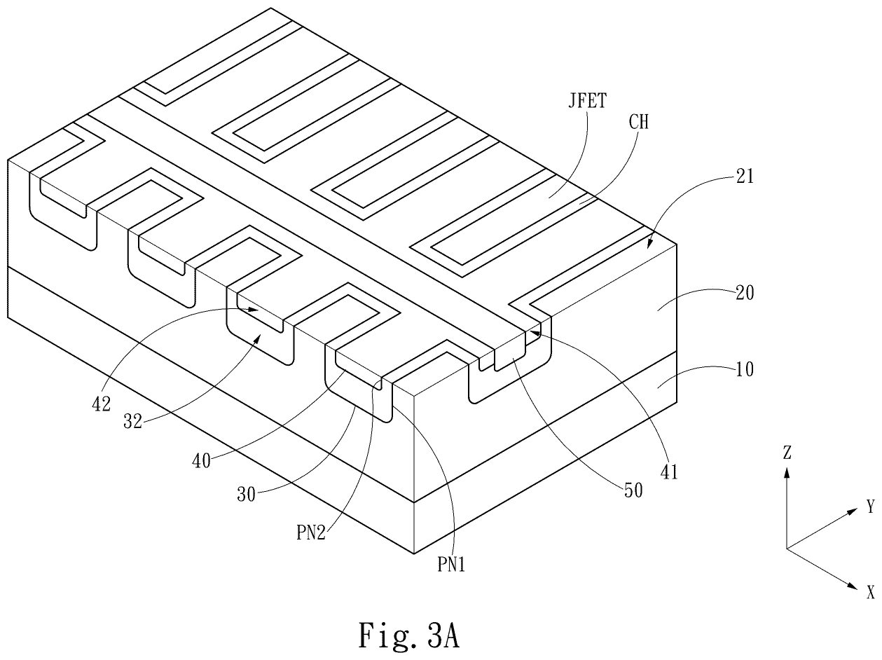

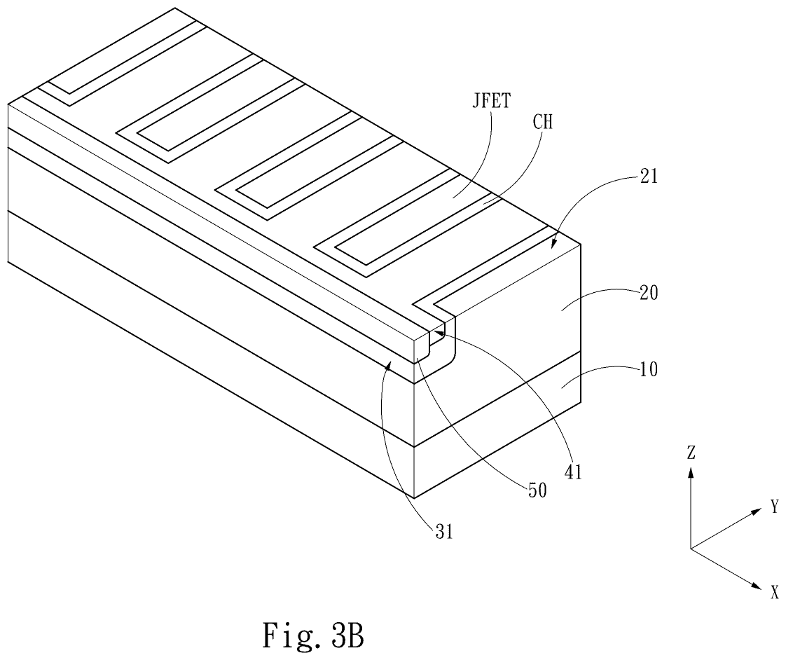

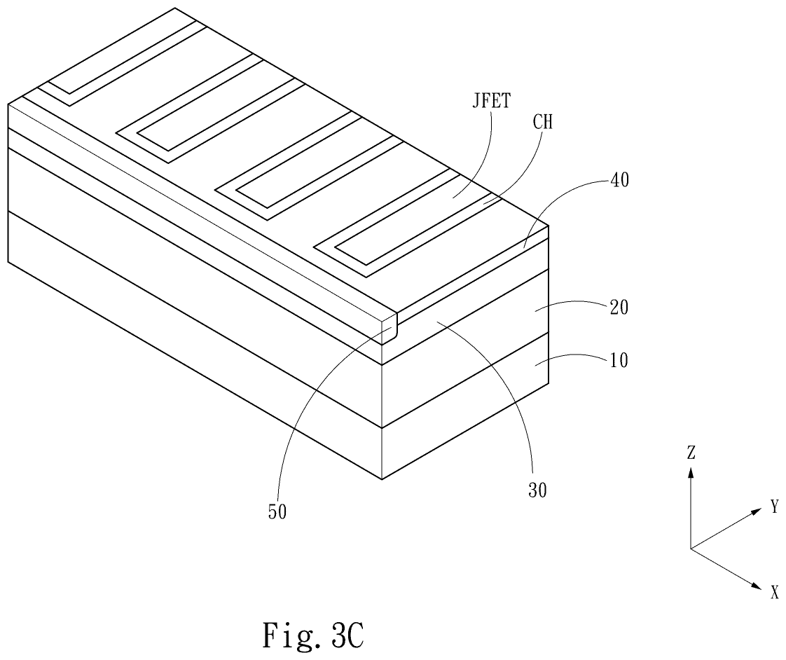

FIG. 2 is a schematic plan view of a silicon carbide semiconductor device 1 according to an embodiment of the present specification, which is taken along the X-Y plane. FIG. 3A depicts a perspective view of the structure along cutting line A1-A2 and line A1-A3 in FIG. 2. FIG. 3B depicts a perspective view of the structure along cutting line A4-A5 and line A4-A3 in FIG. 2. FIG. 3C depicts a perspective view of the structure along cutting line A6-A5 and line A6-A7 in FIG. 2.

The silicon carbide semiconductor device 1 may comprise a silicon carbide substrate 10, a drift layer 20, one or more first doped regions 30, one or more second doped regions 40 and one or more third doped regions 50. The drift layer 20 comprises an active region.

The SiC substrate 10 has a first conductivity type (e.g., N-type) and maybe a nitrogen doped 4H-SiC substrate in an example. Other silicon carbide candidate polytypes may include the 3C, 6H, and 15R polytypes. The drift layer 20 is disposed on the SiC substrate 10 and has the first conductivity type. The first doped regions 30 may be disposed in the drift layer 20 and adjoining to a main surface 21 of the drift layer 20. The first doped regions 30 have a second conductivity type (e.g., P-type), which is opposite to the first conductivity type. The first doped regions 30 may be formed by implanting aluminum ions as dopants into the N-type drift layer to form a counter-doped P-type region adjoining to the main surface 21 of the drift layer 20. The second doped regions 40 is formed by implanting nitrogen ions or phosphorus ions as dopants into the P-type first doped regions 30 to form a heavily doped N-type regions. That is, the second doped regions 40 is disposed in the first doped regions 30.

In the description that follows, for convenience, a direction perpendicular to the main surface 21, that is, a direction parallel to a normal to the main surface 21 shall be referred to as the normal direction Z of the SiC substrate 101. Also, to view from the normal direction Z shall be referred to as plan view. Further, for convenience, a direction perpendicular to the normal direction Z shall be referred to as a first direction X and a direction perpendicular to both the normal direction Z and the first direction X shall be referred to as a second direction Y. The first direction X is different from the second direction Y. In the following non-limiting examples, the wherein the first direction and the second direction are orthogonal to each other.

Referring to FIG. 3A, the first doped regions 30 includes a number of first extending portions 31 and a number of first connecting portions 32, and the second doped regions 40 includes a number of second extending portions 41 and a number of second connecting portions 42 that may be arranged in a cell configuration when viewed in a plan view as shown in FIG. 2. The first extending portions 31 and the second extending portions 41 extend along the first direction X, while the first connecting portions 32 and the second connecting portions 42 extend along the second direction Y.

The cell configuration in FIG. 2 comprises a number of unit cells UC1. Each of the unit cells UC1 comprises two first extending regions 311, 312 and two first connecting regions 321, 322. When viewed in the plan view, the first extending regions 311, 312 run parallel to each other and extend along the first direction X. The first connecting regions 321, 322 also run parallel to each other and extend along the second direction Y. The first extending regions 311, 312 and the first connecting regions 321, 322 are connected with each other. The first doped regions 30 in the unit cell UC1 is elongated linearly, extending in the second direction Y and shaped like a box that surrounds the drift layer 20 laterally (or laterally encircle or be formed circumferentially around). The first doped regions 30 form a plurality of first p-n junctions PN1 and a plurality of JFET regions JFET with the drift layer 20. The drift layer 20 has a first doping concentration of the first conductivity type and the JFET regions JFET have a second doping concentration of the first conductivity type, which is larger than the first doping concentration.

The second doped regions 40 may be disposed in the first doped regions 30. The second extending regions 411, 412 and the second connecting regions 421, 422 are connected with each other. The second extending regions 411, 412 run parallel to each other and extend along the first direction X. The second extending regions 411, 412 is laterally adjacent to the first extending regions 311, 312. The second connecting regions 421, 422 also run parallel to each other and extend along the second direction Y. The second connecting regions 421, 422 is laterally adjacent to the first connecting regions 321, 322. The second extending regions 411, 412 and the second connecting regions 421, 422 are shaped like a mesh that surrounds the first doped regions 30 laterally (or laterally encircle or be formed circumferentially around). The second doped regions 40 form a plurality of second p-n junctions PN2 with the first doped regions 30. A plurality of channel regions CH is provided between the first p-n junctions PN1 and the second p-n junctions PN2 along the main surface 21 of the drift layer 20.

In this embodiment, the first extending portions 31 have a same width and are substantially equally spaced, and the first connecting portions 32 have a same width and are substantially equally spaced. Additionally, the first connecting portions 32 have a same length. In other embodiments, the first extending portions 31 may have different widths, the first connecting portions 32 may also have different widths, and the first connecting portions 32 may have different lengths. Furthermore, the first connecting portions 32 may have a length ranged between 3 μm and 100 μm.

As shown in FIG. 2, the third doped regions 50 are configured to form a multi-stripe structure in the first direction X in the plan view of the silicon carbide semiconductor device 1. The multi-stripe structure comprises a plurality of segments running in parallel to each other. Each of the segments is elongated and runs along an entire width (the length in the first direction X) of the active region.

The third doped regions 50 has the second conductivity type and may be disposed in the first doped regions 30 like the second doped regions 40. The third doped regions 50 run parallel to each other and at least partially extended with the first extending portions 31 and second extending portions 41 along the first direction X. The third doped region 50 is laterally adjacent to the second extending portions 41. In this embodiment, each of the third doped region 50 may extend across the active region of the silicon carbide semiconductor device 1, through which a main current flows. In one example, the third doped region 50 may comprise a plurality of dashed or dotted regions.

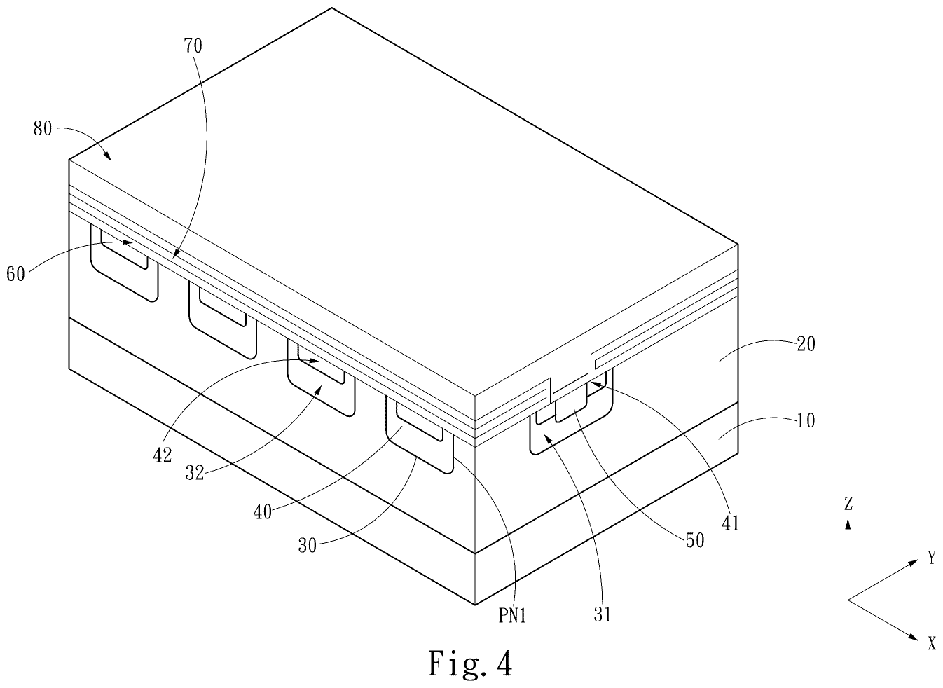

Referring now to FIG. 4, the silicon carbide semiconductor device 1 may further comprises a gate insulator 60, a gate electrode 70, and a source electrode 80. The gate insulator 60 is disposed on the main surface 21 of the drift layer 20 and extends over the JFET regions JFET, the channel regions CH, and a first part of the second doped regions 40. The gate electrode 70 contacts the gate insulator 60. The gate insulator 60 and the gate electrode 70 form a gate region disposed above the drift layer 20, the first doped regions 30 and the first part of the second doped regions 40. The source electrode 80 contacts at least a portion of the second doped regions 40 and at least a portion of the third doped regions 50 through a plurality of source contact regions.

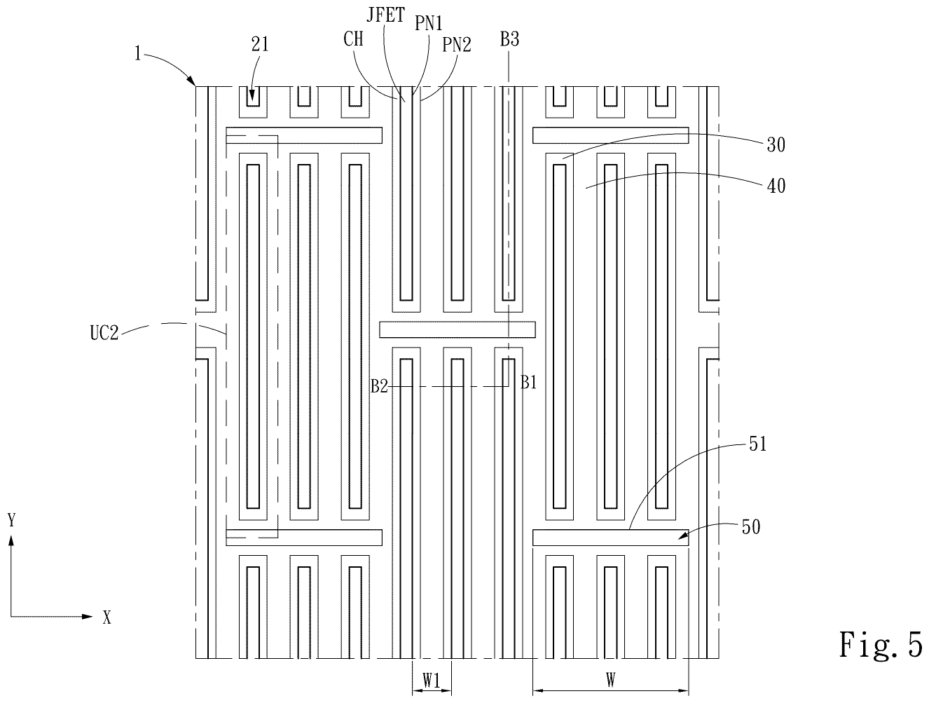

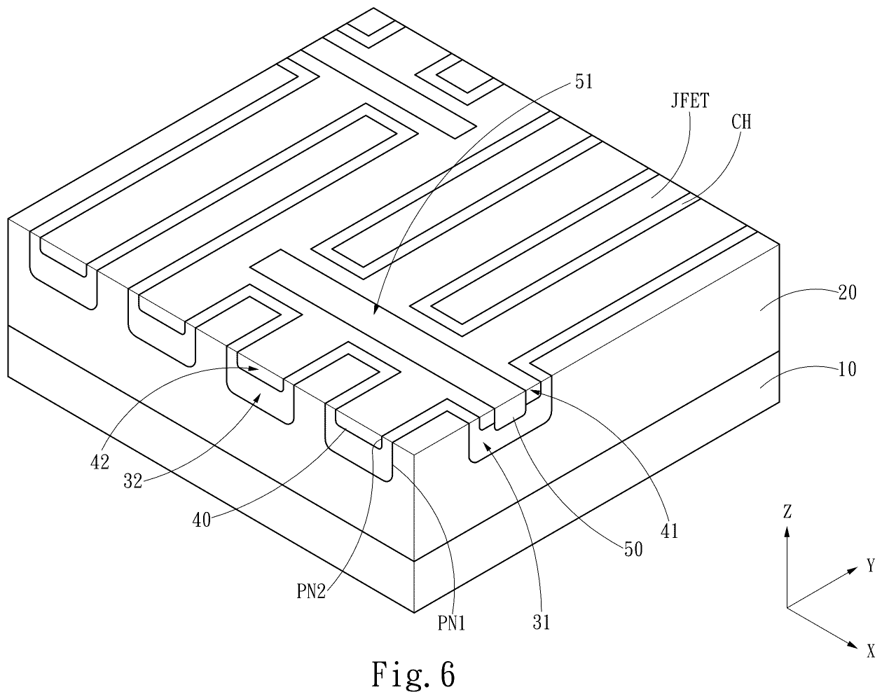

FIG. 5 exemplarily illustrates a schematic plan view of a silicon carbide semiconductor device according to another embodiment of the present specification. FIG. 6 depicts a perspective view of the structure along cutting line B1-B2 and line B1-B3 in FIG. 5. As another embodiment of the present specification, each of the third doped regions 50 is formed as a broken stripe shape along the first direction X when viewed in a plan view as shown in FIG. 5.

Each of the third doped regions 50 comprises one or more segments 51 laterally extending along the first direction X. Each of the segments 51 is elongated and runs along a width W (the length in the first direction X) of the active region. That is, each of the segments 51 runs along a portion of the entire width of the active region instead of the entire width. Furthermore, the width W satisfies the following relationship:

$$3 * W 1 \leq W \leq 20000 * W 1$$

W1 denotes a width of the first connecting portion 32.

In particular, the adjacent parallel segments 51 in the adjacent rows are displaced from each other. A displacement between the adjacent parallel segments 51 is substantially equals to a pitch between the adjacent segments 51 in the first direction X. It is possible that the displacement is a value other than the pitch between adjacent segment 51. Namely, the displacement may be larger or smaller than the pitch between adjacent segment 51.

One of the advantages of the present disclosure is owing to the geometrical configuration of the third doped regions. According to a calculation, the channel width density may be increased due to the configuration described above. According to one or more embodiments, the channel width density of the active region is higher than 0.2 μm⁻¹. According to other embodiments, the channel width density of the active region is higher than 0.4 μm⁻¹.

For the purpose of demonstrating some of the possible configurations, possible and non-limiting exemplary dimensions are shown in Table 1, based on the structure illustrated with reference to FIGS. 2 and 3A to 3B.

TABLE 1
Comparison of cell pitch and channel width density

| | Min. dimension of | | | | Channel Width |
|---|---|---|---|---|---|
| No. | contact openings | | Cell Pitch (μm) | | Density |
| STRIP-I | 1 | μm | 4.8 | μm | 0.416 μm⁻¹ |
| Example 1 | 1 | μm | 3.2 | μm | 0.561 μm⁻¹ |
| Example 2 | 1 | μm | 2.7 | μm | 0.665 μm⁻¹ |
| STRIP-II | 0.4 | μm | 3 | μm | 0.667 μm⁻¹ |
| Example 3 | 0.4 | μm | 2 | μm | 0.912 μm⁻¹ |

Considering the minimum width of the contact openings is 1 μm, the minimum overlap of the gate electrode 70 and n+ regions (the second doped regions 40) is 0.3 μm, the minimum spacing between the gate electrode 70 and the contact opening is 0.5 μm and the channel length is 0.5 μm, the minimum width of the JFET regions JFET is 1.2 μm, then the minimum cell pitch for conventional strip layout (STRIP-I) is (1+(0.3+0.5+0.5)*2)+1.2=4.8 μm, and the channel width density is 2/4.8=0.416 μm⁻¹.

With present invention, the minimum cell pitch will not be limited by the minimum width of the contact openings. Only the minimum width of the first extending portions 31 will be limited by the minimum width of the contact openings. In Example 1, with the same design rules mentioned above, the minimum width of the first extending portions 31 is (1+(0.3+0.5+0.5)*2)=3.6 μm. If the width of the first connecting portions 32 is 2 μm, the width of the second connecting portions 42 will be 1 μm. Since the width of the JFET regions JFET is 1.2 μm, the cell pitch will become 2+1.2=3.2 μm, smaller than the conventional strip layout (STRIP-I). If the length of the first connecting portions 32 is 20 μm, the channel width density will be 0.561 μm⁻¹, about 35% higher than conventional strip layout (STRIP-I).

In modern SiC planar MOSFETs, the channel regions are defined by the self-align processes, such as hardmask sidewall spacers formed by etching back, thus the minimum width of n+ regions (the second doped regions 40) are not limited by photolithography. In Example 2, if the width of the first connecting portions 32 is reduced to 1.5 μm, the width of the second connecting portions 42 will become 0.5 μm, and the cell pitch with 1.2 μm width of JFET regions will become 2.7 μm and the channel width density will be 0.665 μm⁻¹, about 60% higher than conventional stripe layout.

With the commercially available 200 mm thickness substrate, the manufacturable minimum dimensions of SiC MOSFETs are also improving due to better photolithography and etching system. Considering the minimum width of the contact openings improves to 0.4 μm, the minimum overlap of the gate electrode 70 and n+ regions (the second doped regions 40) is 0.2 μm, the minimum spacing between the gate electrode and contact opening is 0.3 μm and the channel length is 0.4 μm, the minimum width of JFET regions JFET is 0.8 μm, then the minimum cell pitch for conventional strip layout (STRIP-II) is (0.4+(0.2+0.3+0.4)*2)+0.8=3 μm, and the channel width density is 2/3=0.667 μm⁻¹.

With present invention, the minimum cell pitch will not be limited by the minimum width of contact openings. Only the minimum width of the first extending portions will be limited by the minimum width of contact openings. In yet one embodiment (Example 3), with the same design rules mentioned above, the minimum width of the first extending portions is (0.4+(0.2+0.3+0.4)*2)=2.2 μm. If the width of the first connecting portions 32 is 1.2 μm, the width of the second connecting portions will be 0.4 μm. Since the width of JFET regions is 0.8 μm, the cell pitch will become 1.2+0.8-2 μm, smaller than the conventional strip layout. If the length of the first connecting portions 32 is 20 μm, the channel width density will be 0.912 μm⁻¹, about 37% higher than conventional strip layout. There is flexibility to use a relaxed design rules but achieve the similar channel width density compared to conventional stripe layout with strict design rules, to improve the manufacturability and yield, or to pursue a highest possible channel width density with strict design rules.

What is claimed is:

1. A silicon carbide semiconductor device, comprising:
a silicon carbide substrate;
a drift layer of a first conductivity type having a first doping concentration disposed on the silicon carbide substrate, wherein the drift layer has a main surface and comprises an active region;
a plurality of first doped regions of a second conductivity type opposite to the first conductivity type disposed in the active region, the first doped regions comprising a plurality of first extending portions extended laterally along a first direction and a plurality of first connecting portions extended laterally along a second direction different from the first direction, wherein each of the first connecting portions laterally connects a pair of the first extending portions in the second direction, and the first doped regions form a plurality of first p-n junctions and a plurality of JFET regions with the drift layer;
a plurality of second doped regions of the first conductivity type disposed within the first doped regions, the second doped regions comprising a plurality of second extending portions extended laterally along the first direction and a plurality of second connecting portions extended laterally along the second direction, wherein each of the second connecting portions laterally connects a pair of the second extending portions in the second direction, and the second doped regions form a plurality of second p-n junctions with the first doped regions, and a plurality of channel regions being provided between the first p-n junctions and the second p-n junctions along the main surface;
a plurality of third doped regions of the second conductivity type disposed in the first extending portions of the first doped regions and adjacent to the second extending portions of the second doped regions, wherein the third doped regions is at least partially extended with the first and second extending portions along the first direction;
a gate insulator disposed on the main surface, wherein the gate insulator extends over the JFET regions, the channel regions, and a part of the second doped regions;
a gate electrode contacting the gate insulator; and
a source electrode contacting at least a portion of the second extending portions of second doped regions and the third doped regions through a plurality of contact openings.

2. The silicon carbide semiconductor device of claim 1, wherein the first direction and the second direction are orthogonal.

3. The silicon carbide semiconductor device of claim 1, wherein the first extending portions have a same width and are substantially equally spaced.

4. The silicon carbide semiconductor device of claim 1, wherein the first connecting portions have a same width and are substantially equally spaced.

5. The silicon carbide semiconductor device of claim 1, wherein the first extending portions have different widths.

6. The silicon carbide semiconductor device of claim 1, wherein the first connecting portions have different widths.

7. The silicon carbide semiconductor device of claim 1, wherein the first connecting portions have a same length.

8. The silicon carbide semiconductor device of claim 1, wherein the first connecting portions have different lengths.

9. The silicon carbide semiconductor device of claim 1, wherein the first extending portions, the second extending portions and the third doped regions are configured to form a multi-stripe structure in the first direction in a plan view of the silicon carbide semiconductor device.

10. The silicon carbide semiconductor device of claim 9, wherein the multi-stripe structure comprises a plurality of segments, and wherein each of the segments is elongated and runs along an entire width of the active region.

11. The silicon carbide semiconductor device of claim 10, wherein the segments run in parallel to each other.

12. The silicon carbide semiconductor device of claim 9, wherein each of the third doped regions is elongated and runs along a width W in the active region, and wherein the width W satisfies the following relationship:
3*W1≤W≤20000*W1
wherein W1 denotes a width of the first connecting portion.

13. The silicon carbide semiconductor device of claim 9, wherein the multi-stripe structure comprises a plurality of segments, and wherein each of the segments is elongated and runs along a portion of an entire width of the active region.

14. The silicon carbide semiconductor device of claim 13, wherein the segments run in parallel to each other.

15. The silicon carbide semiconductor device of claim 14, wherein the adjacent parallel segments are displaced from each other.

16. The silicon carbide semiconductor device of claim 14, wherein a displacement between the adjacent parallel segments is substantially equals to a pitch between the adjacent segments in the first direction.

17. The silicon carbide semiconductor device of claim 1, wherein a length of the first connecting portions is ranged between 3.2 μm and 100 μm.

18. The silicon carbide semiconductor device of claim 1, wherein the JFET regions have a second doping concentration of the first conductivity type larger than the first doping concentration.

19. The silicon carbide semiconductor device of claim 1, wherein the third doped region comprises a plurality of dashed or dotted regions.

20. The silicon carbide semiconductor device of claim 1, where a channel width density of the active region is higher than 0.2 μm⁻¹.
